(19) United States
(12) Patent Application Publication
(10) Pub. No.: US 2004/0159930 A1
(43) Pub. Date: Aug. 19, 2004

(54) Semiconductor device, method of manufacturing the same, and electronic device using the semiconductor device

(76) Inventors: Yoshihiro Makita, Chiba-shi (JP); Kiyohito Endou, Chiba-shi (JP)

Correspondence Address: ADAMS & WILKS, 31st Floor, 50 Broadway, New York, NY, 10004, US

(21) Appl. No.: 10/644,716

(22) Filed: Aug. 20, 2003

(30) Foreign Application Priority Data
Aug. 30, 2002 (JP) 2002-253240

(51) Int. Cl. H01L 23/48

(52) U.S. Cl. 257/690

(57) ABSTRACT

To provide a low-cost semiconductor device that obtains a reduction in pitch and an increase in the number of pins using conventional equipment and to provide a method of manufacturing the semiconductor device. The semiconductor device according to the present invention includes: a flexible printed circuit, on which a semiconductor chip is mounted, having a connection terminal portion that includes a plurality of land-shaped connection terminals arranged in a step form or a grid form and an insulating film provided to a conductor connected with the respective land-shaped connection terminals. Further, a method of manufacturing a semiconductor device according to the present invention includes: forming a flexible printed circuit including a connection terminal portion in which a plurality of land-shaped connection terminals are arranged in a step form or a grid form and an insulating film is provided to a conductor connected with the respective land-shaped connection terminals; mounting a semiconductor chip on the flexible printed circuit; and separating a semiconductor device from the flexible printed circuit by cutting a portion of each of outermost land-shaped connection terminals.

### BACKGROUND OF THE INVENTION

The present invention relates to a semiconductor device used for electronic parts and a method of manufacturing the semiconductor device. More particularly, the present invention relates to a structure of a flexible printed circuit (hereinafter referred to as FPC) or a tape carrier package (hereinafter referred to as TCP) on which semiconductor chips are mounted, and an electronic device using these semiconductor devices.

A display device using a display panel such as a plasma panel or a liquid crystal panel is given as an example of an electronic device having a display screen. The display device includes a display panel composed of a transparent substrate in which wirings made from metallic thin films are provided, and a semiconductor device that drives the display device. As the semiconductor device, a device obtained by cutting the above-mentioned tape-shaped TCP in a predetermined shape using a die mold or a device obtained by cutting a sheet FPC in a predetermined shape using a die mold is used. Such a semiconductor device is bonded by pressure to the display panel by the following method. An anisotropic conductive film (hereinafter referred to as ACF) is bonded onto an end portion of the display panel, image recognition is conducted on marks of alignment between a terminal of the FPC or the TCP and the terminal of the transparent substrate, and the semiconductor device is pressed while the ACF on the board is heated at approximately 80° C., thereby temporally bonding the semiconductor device to the board. Next, the semiconductor device is pressed again from the film side of the FPC or the TCP while heated at approximately 200° C. Accordingly, conductive particles in the ACF are flattened to obtain electrical connection, thereby completing the connection. Hereinafter, more detailed description will be made with reference to FIGS. 1 to 3.

As shown in FIG. 1, terminals 2 which are formed in parallel are provided on an edge portion of a transparent substrate composing a display panel 1. On the other hand, as shown in FIG. 2, connection terminals 5 on a wiring board of a TCP 4 in which an IC chip 8 is provided are formed in the same shape and size as the terminals 2 on the transparent substrate. An ACF 3 is bonded onto the terminal portion of the transparent substrate. Further, a wiring plate alignment mark 7 of the TCP 4 is aligned with the transparent substrate side alignment mark 6 while image processing is conducted, and then the terminals 2 of the transparent substrate is connected with the connection terminals 5 of the TCP 4 by thermo compression bonding.

FIG. 3 is a schematic view showing that a TCP tape 9 is cut using a predetermined mold to obtain the TCP 4. After the TCP 4 is cut in a predetermined shape, the transparent substrate side alignment mark 6 is aligned with the wiring plate alignment mark 7 of the TCP by image recognition. Then, the ACF 3 provided to the terminals 2 of the transparent substrate is heated from the film side of the TCP 4, so that an adhesive portion of the ACF 3 is melted and cured. At this time, because of the pressure, the conductive particles in the inner portion of the ACF are flattened, with the result that the terminals 2 of the transparent substrate can be electrically connected with the connection terminals, 5 of the TCP 4 through the particles of the ACF. Here, after the IC chip 8 is mounted on the TCP tape 9, a test is conducted using a test terminal 10 in order to check the operation of the IC chip 8. The test terminal 10 is used as a test pad in TCP tape manufacturing makers as well as semiconductor makers. The TCP 4 is die-cut from the TCP tape 9, and a cutting hole 11 is left in the TCP tape 9. The TCP 4 is die-cut so as not to include the test terminal 10. Therefore, after the TCP 4 is separated from the TCP tape 9, the test terminal 10 is not used.

FIG. 4 is a partially enlarged sectional view showing a connection portion between the transparent substrate of the display panel 1 in which the ACF is omitted and the terminal 5 of the TCP 4. As shown in FIGS. 1 and 4, conventional patterns of a connection portion are uniformly arranged in parallel, the connection terminals 5 of the TCP 4 are aligned with the terminals 2 of the transparent substrate, and both the terminals are bonded to each other through the ACF. In recent years, a terminal pitch for bonding both the terminals is narrowed. Further, in order to improve mounting efficiency, the number of pins tends to increase. Therefore, problems with respect to manufacturing due to a reduction in pitch and an increase in the number of pins are caused.

A first problem with respect to the connection terminals whose pitch is narrowed is that a peeling strength is insufficient. When a film sheet or a film tape is die-cut using a mold, patterns formed in a narrow pitch are partly peeled off from the film sheet or the film tape in a fine split state due to a die-cut resistance, and come into contact with a pattern wiring portion adjacent thereto, thereby causing an electrical short circuit. FIG. 5 shows a state in which the connection terminals are partly peeled off from a film substrate and the short circuit may be caused. That is, when die-cutting is conducted using a mold, terminal peeling is caused in terminals 12 and 13 which are parts of the connection terminals 5. If such a film substrate is connected with a display panel, poor display occurs.

Also, as shown in FIG. 6, an anisotropic conductive film 14 in which conductive particles 51 are mixed in an adhesive is used to connect circuit boards having patterns with each other, and the conductive particles are flattened to obtain electrical connection. Therefore, in the case where the circuit boards having patterns formed in a narrow pitch are connected with each other, when the connection reliability of terminals of-both the circuit boards is ensured, it is necessary to distribute as many of the conductive particles 51 as possible within a contact surface of the terminals of both the circuit boards between the opposed terminals thereof. That is, when the first problem is solved, high level requirements and storage control are required for pattern manufacturing precision of the FPC, film material properties, and the like because the alignment of the terminals of both the circuit boards affects the connection reliability.

Also, with narrowing a pitch of the connection terminals, a large number of pins can be arranged at high density within an area conventionally used. An outline of the wiring portion and the bonding portion are artificially checked using a microscope or the like. In recent years, in order to electrically conduct determination of a defect such as a short circuit or a disconnection, a test land is provided for each of the connection terminals. Because the test land connected with each of the connection terminals is unnecessary as an electronic part mounted on a display device, the test land is separated from each of the connection terminals of the FPC or the TCP and discarded. As the number of pins increases, an arrangement area of the test lands becomes larger than an area of the TCP or the FPC which are actually used, thereby increasing pressure on member costs of the TCP and the FPC. This is a third problem.

### SUMMARY OF THE INVENTION

In order to solve the above-mentioned respective problems, an object of the present invention is to provide an electronic part including a semiconductor device package, in which pattern peeling in die-cutting and poor connection due to the pattern peeling are prevented, connection precision between boards when a pitch is narrowed is improved, and a material cost is reduced, and to provide a manufacturing method thereof.

According to a structure with respect to the first problem, in order to increase a peeling strength, land-shaped specific connection terminals are arranged in step or grid and an outer size width of a connection land is set to a land size capable of testing so as to commonly use test terminals and connection terminals.

In addition, according to a connection terminal structure for TCP and glass boards with respect to the second problem, a wiring pitch to each land is set to a wiring pitch capable of etching and a region other than lands to be connected is covered with an organic insulating resin or the like using a printing method or a photolithography method to increase a pitch between the connection terminals.

Further, according to a structure with respect to the third problem, a reduction in a use area of a base member due to common use of terminals is possible.

### BRIEF DESCRIPTION OF THE DRAWINGS

In the accompanying drawings:

FIG. 1 is a perspective view for explaining a connection between a display panel and a TCP;

FIG. 2 is a perspective view showing a structure of the display panel and a structure of the TCP;

FIG. 3 is a perspective view showing a package form of the TCP;

FIG. 4 is an enlarged perspective view showing a connection portion between the display panel and the TCP;

FIG. 5 is a perspective view for explaining a poor state of the connection portion of the TCP;

FIG. 6 is a sectional view for explaining ACF bonding;

FIG. 7 is a schematic view showing a connection terminal portion according to an embodiment of the present invention;

FIG. 8A is a schematic view showing a die-cut shape according to the present invention and FIG. 8B is a schematic view showing a die-cut shape according to a conventional method;

FIG. 9 is a perspective view for explaining die-cutting according to the present invention;

FIG. 10 is an enlarged perspective view for explaining a connection structure of the present invention;

FIG. 11 is a schematic sectional view for explaining ACF bonding according to the present invention; and

FIG. 12 is a detailed view of a connection terminal unit portion according to the present invention.

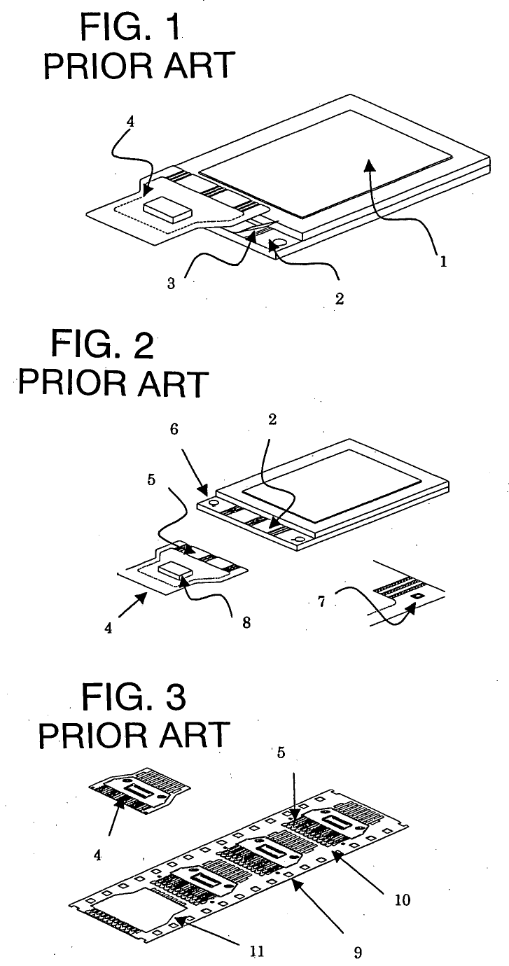

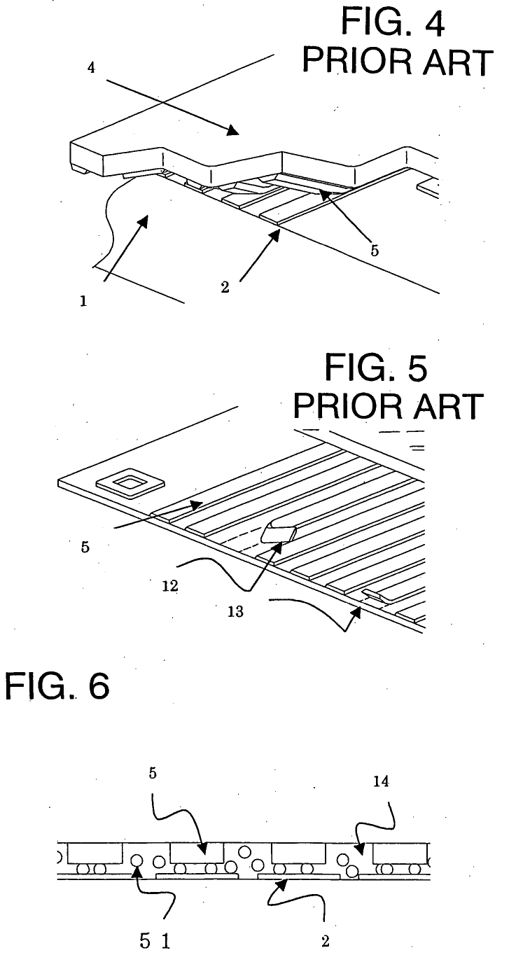

### DETAILED DESCRIPTION OF THE PREFERRED EMBODIMENT

A semiconductor device according to the present invention includes a flexible printed circuit and a semiconductor chip mounted on the flexible printed circuit. The flexible printed circuit includes a plurality of land-shaped connection terminals arranged in a step form or a grid form. Further, the flexible printed circuit has a connection terminal portion. In the connection terminal portion, an insulating film provided to a wiring connected with the respective land-shaped connection terminals. Further, the land-shaped connection terminals are commonly used as terminals for electrical test.

Further, a method of manufacturing a semiconductor device according to the present invention includes: forming a flexible printed circuit including a connection terminal portion in which a plurality of land-shaped connection terminals are arranged in a step form or a grid form and an insulating film is provided to a conductor connected with the respective land-shaped connection terminals; mounting a semiconductor chip on the flexible printed circuit; and separating a semiconductor device from the flexible printed circuit by cutting a portion of each of outermost land-shaped connection terminals.

Further, the method of manufacturing a semiconductor device according to the present invention includes a test step of performing an electrical test using the land-shaped connection terminals. Here, the semiconductor chip is tested in this test step. Alternatively, a pattern test of the flexible printed circuit is performed in this test step.

Further, an electronic device according to the present invention includes: a flexible printed circuit having a connection terminal portion that includes a plurality of connection terminal lands arranged in a step form or a grid form and an insulating film provided to a conductor connected with the respective connection terminal lands; a semiconductor chip mounted on the flexible printed circuit; and an electronic part operated at a time when an output signal from the semiconductor chip is inputted through the plurality of connection terminal lands.

Further, the electronic part includes a terminal portion provided in a region connected with the flexible printed circuit, and the terminal portion includes terminals provided at positions opposed to the connection terminal lands of the flexible printed circuit and a plurality of wirings which are connected with this terminals and covered with an insulating film.

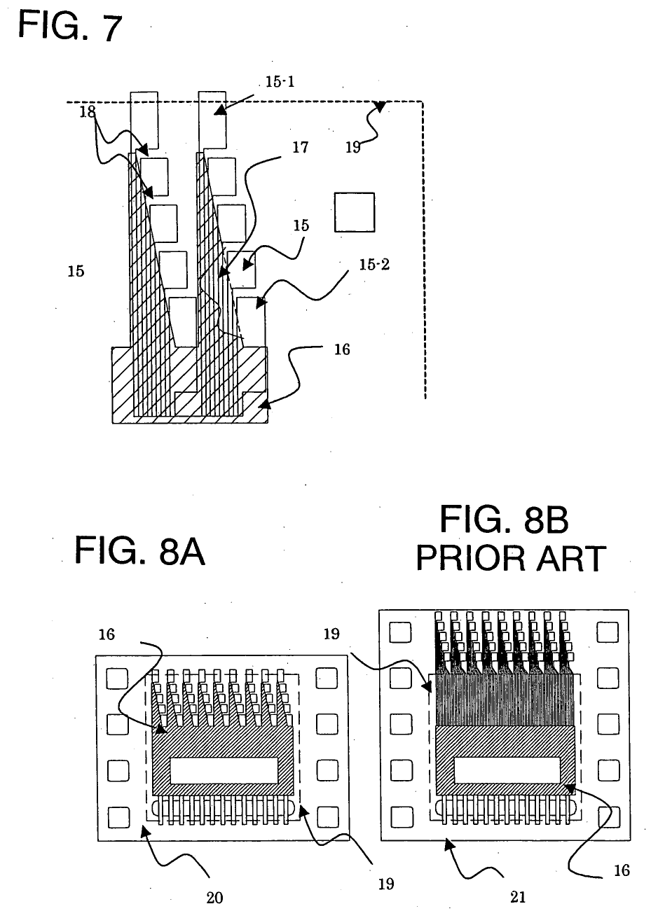

Next, a main part of the present invention will be described with reference to FIG. 7. FIG. 7 is an enlarged plan view showing connection terminals on a TCP side or a FPC side. As shown in FIG. 7, the connection terminals are formed in land shapes (lands 15). Further, wirings 17 are formed at a minimum pitch which allows an etching process. Here, in order to suppress a disconnection due to external stress or the like, a position displacement, a short circuit due to dust or the like, an organic insulating film 16 is provided to protect the wirings 17. At this time, similarly, a space other than the terminals is protected on a transparent board side of the display panel by an insulating film such as the organic insulating film 16. Accordingly, a connection reliability can be improved. A dot line 19 indicates a cutting line for cutting in a predetermined shape suitable for use of the TCP, the FPC, or the like. When cutting in the predetermined shape is conducted using a mold or the like, an outermost land portion is formed by cutting an outermost land 15-1 such that it becomes the same shape as those of other lands 15. As a result, widths of the lands are three times wider than those of conventional connection wirings 5, thereby enhancing an absolute peeling strength.

Also, when the connection terminals of the TCP are formed in the land shape, the test terminals and the connection terminals can be commonly used and parallel and uniform specific connection terminals conventionally required become dispensable. Accordingly, sizes of the TCP and the FPC can be reduced. In addition, when the connection terminals are formed in the land shape, a pitch between the lands becomes rough in a right-and-left direction of each of the lands, so that high level precision becomes unnecessary for alignment between the transparent board and the TCP or the FPC and high outer size precision becomes unnecessary.

Table 1 shows a relationship between a land size and a position displacement allowance and the number of steps in an area in which a connection terminal length is 1.5 μm in the case of a pitch of 54 μm.

TABLE 1

| | | Three | | |
|---|---|---|---|---|
| | Two steps | steps | Four steps | Five steps |
| Land width (μm) | 35 | 44 | 53 | 62 |
| Land length (μ) | 720 | 465 | 332 | 260 |
| Land area (μm²) | 25200 | 20460 | 17596 | 16120 |
| Position displacement | ±16 μm | ±15 μm | ±12 μm | ±10 μm |
| allowance when contact | | | | |
| area is 13500 μm² | | | | |

Precondition: 54 μm pitch product
TCP side connection terminal area: 27000 μm² = 1500 μm in Length × 18 μm in width Contact area when position displacement is 9 μm (1/2 of terminal width): 13500 μm²

As is apparent from Table 1, high level connection position size precision is unnecessary.

Hereinafter, an embodiment of the present invention will be described in detail with reference to the drawings.

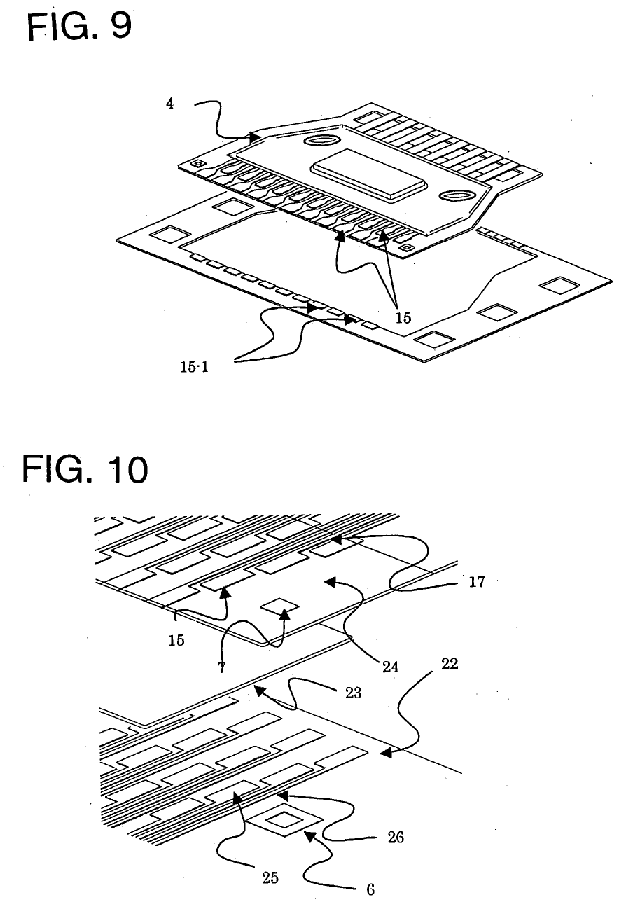

A terminal structure of this embodiment relates to a structure in which test terminals and specific connection terminals are commonly used and arranged in a step shape or a grid shape. FIG. 7 is a partially enlarged view showing a layout of connection lands in which five-step connection terminals having a pitch of 54 μm are provided. FIG. 8A is an entire view of a carrier tape in which such a TCP is provided. FIG. 10 shows lands of the TCP and terminals of a display panel, which are connected with the lands of the TCP. In addition, FIG. 9 is a schematic view showing that a TCP having connection lands composed of two-step connection terminals is formed by die-cutting it from a carrier tape.

The semiconductor device of the present invention does not include the conventional specific connection terminals which are called outer leads, and the connection portions are formed in a land shape such that they can also used as the test terminals. An outer size of each of the lands 15 as the connection terminals is set to 63 μm×260 μm. When the TCP is cut from a base member along a cutting line 19 with die-cut position precision of ±150 μm, a size of each of the lands 15-1 is set to 63 μm×410 μm so as to correspond each of the lands 15-1 to the above land outer size. Further, even in the case of lands 15-2, a region from a semiconductor chip to a connection terminal land portion is covered with the organic insulating film 16 using a photolithographing method or a printing method. In order to increase the land width size, it is necessary to set a minimum pitch which allows etching of the wirings 17. In a conventional case, the wirings to the test terminals are not covered with the organic insulating film. Therefore, in order to prevent a short circuit, dust, trash and the like are forced to be removed using a conductive dust brush or the like. On the other hand, according to the present invention, the wirings 17 are covered with the organic insulating film 16. Accordingly, a mechanical defect due to external stress can be prevented. In addition, defects such as a disconnection, a short circuit due to dust, trash, or the like, and a short circuit due to a degradation in position precision and repeat precision of a mounted device and a mounted material can be prevented. Note that a relationship between the width of each of the lands 15 and the number of steps becomes the relationship shown in Table 1, and it is apparent that the land width direction increases as the number of steps increases. Here, a copper foil having a thickness of 8 μm is used for the wirings 17, and 40 μm is used as the minimum pitch.

When a layout is effected based on the precondition, it is apparent that an increase in the number of steps contributes to an increase in the land width. Further, when a position displacement size allowance to the conventional wiring width of 18 μm is ½ of the terminal width, that is, when a connection displacement of 9 μm is caused, a contact area in a conventional product becomes 13500 μm² and reduced by 50%. However, when a connection terminal width is increased, the contact area is reduced by only about 25% in the case where the land width is 35 μm because the amount of displacement of 9 μm has a proportional relationship with the width. Accordingly, as for narrow pitch connection, even if machine repeat precision is reduced, a connection reliability can be ensured.

Therefore, the land width increases as the number of steps increases, so that, with respect to a displacement in a transverse direction, the TCP as shown in FIG. 8A, which has the same terminals as in the case of narrow pitch bonding can be supplied by a conventional control method. A product 20 according to the present invention (FIG. 8A) and a conventional part 21 (FIG. 8B) which are surrounded by the cutting line 19 are identical in shape. However, as compared with the conventional part 21, the used outer size of the part 20 according to the present invention can be reduced by one of sprocket halls 22. Accordingly, the area of the base member is reduced, with the result that a cost can be suppressed.

As described above, when the connection lands are used as the lands for conduction test, the area having the specific connection terminal length, which is conventionally used can be reduced. Thus, a reduction in size of the TCP is realized, and the above-mentioned connection lands contribute to high density mounting and a reduced member cost.

As shown in FIG. 3, the part according to the present invention is also incorporated in a film tape which becomes a base member as in a conventional case. Therefore, it is necessary to separate the part from the film tape using a predetermined mold or the like. Up to now, when specific connection wirings having a narrow pitch are cut, close attention is paid to a longitudinal direction of patterns of the TCP device to a convex mold, an abrasion degree of a cutting part, a clearance of convex and concave portions of the mold, and the like. As for the part according to the present invention, as shown in FIG. 7, each of the lands has a connection terminal width five or more times larger than a conventional narrow pitch part (75 μm part). With increasing the width, a bonding strength value three to six times larger than the conventional part can be also obtained. Further, it is unnecessary to pay close attention to the abrasion degree of the cutting part and a die-cut direction of the TCP device by using the mold. Accordingly, the part according to the present invention contributes to a reduced cost in terms of productivity and maintenance because a life of the mold increases. A short circuit defect due to peeling of the specific connection terminal from the base member in the conventional part mounted on the display panel is eliminated by increasing a terminal bonding force. Thus, a mounting yield can be improved and a waste cost resulting from the defect can be greatly reduced.

Next, a method of using the part according to the present invention and a method of connecting a display panel therewith will be described. FIG. 10 shows an ACF 23 between terminals 22 on the display panel side and connection terminals 24 of the TCP or the FPC. Display panel terminal lands 25 are provided corresponding to the TCP terminal lands 15 on the display panel side. In addition, wirings 26 to the terminals are similarly provided. The ACF 23 is bonded onto the terminals 22 on the display panel side, and then image processing is performed on an alignment mark 6 on the display panel side and an alignment mark 7 on the TCP side to complete the alignment between the terminals on both sides. After that, with a state in which the ACF 23 is interposed between the display panel and the TCP, the connection terminals 24 of the TCP are heated and pressed from the above to complete bonding of the respective terminals on both sides. At the time of terminal connection, because a conventional mounting apparatus is used, a terminal connection position displacement equal to that of a conventional case is caused. However, as shown in FIG. 7, there is no case where a short circuit phenomenon between the terminals is caused because the wirings 17 adjacent to the TCP connection terminal lands are covered with the organic insulating film 16. Further, when the upper portion of the wirings 17 adjacent to the display panel terminal lands are covered with the insulating film as in the case of the wirings 17 adjacent to the TCP connection terminal lands, a short circuit phenomenon defect due to position displacement and the like can be avoided, which is convenient. Thus, a bonding technique for ACF bonding in the case where a pitch is narrowed and the number of pins are increased can be provided without modifying the conventional apparatus.

FIG. 11 is a sectional view showing a state in which both the display panel terminal lands 25 and the connection terminal lands 15 of the TCP or the FPC are connected with each other through ACF particles 5-2. As shown in FIG. 11, as for a region other than the connection terminal surface, the wirings 17 on the TCP or FPC side are covered with the organic insulating film 16 on the TCP or FPC side. In addition, the wirings 26 of the display panel are also covered with the insulating film as in the case of the wirings 17 of the TCP, so that the terminals are insulated from one another. That is, the ACF particles 5-2 are in contact with only both terminal surfaces which are not insulated, so that a connection state can be maintained through a resin of the ACF.

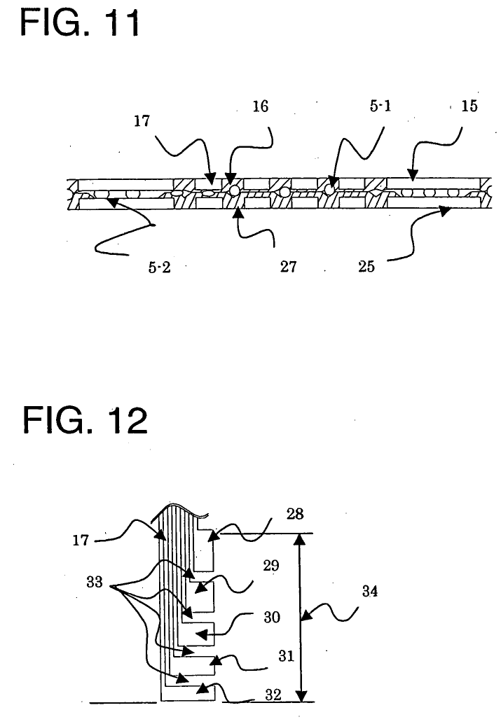

FIG. 12 shows a layout of connection terminal lands in the case where a connection land area is kept constant. Note that the insulating film is omitted here. When the connection terminal lands are completely isolated from one another through the insulating film, as shown in FIG. 12, the arrangement of the connection terminal lands in which the connection land area is kept constant is made possible. Accordingly, a further high density arrangement of the connection terminal lands can be realized. At this time, the respective terminal sizes are shown as follows in Table 2, so that bonding several times easier than in a connection part having specific connection terminals at a pitch of 54 μm is made possible. Here, after cutting in a predetermined shape, it is necessary that a connection terminal land 32 in the case of the TCP or the FPC become 70 μm.

TABLE 2

| | No. | | | | |
|---|---|---|---|---|---|
| | 28 | 29 | 30 | 31 | 32 |
| Length (μm) | 200 | 145 | 110 | 90 | 70 |
| Width (μm) | 90 | 130 | 170 | 210 | 250 |
| Area (μm²) | 18000 | 18200 | 18700 | 18900 | 17500 |

Note that respective conditions designed in the above-mentioned Table 2 are as follows.
Land terminal arrangement length 34: 815 μm
Gap between terminals 33: 50 μm
Wiring pitch 17: 40 μm

Therefore, in the case where specific connection terminals have a pitch of 54 μm, a terminal width is 22 μm, a length is 1000 μm, and an area is 22000 μm². If the position displacement allowance value becomes a half of a lead width, that is, 11 μm, the area becomes 11000 μm². However, according to the part in the present invention, even if a displacement of 11 μm is caused, the area becomes 15800 μm². Accordingly, the existence probability of conductive particles in the ACF becomes higher than that in the conventional part, with the result that the connection reliability is improved.

As described above, when the connection lands are used as the lands for conduction test, the area having the specific connection terminal length, which is conventionally used can be reduced. Thus, a reduction in size of the TCP is realized. In addition, the contribution to high density mounting and a reduction in member cost can be realized.

What is claimed is:

1. A semiconductor device comprising:
a flexible printed circuit having a connection terminal portion that includes a plurality of land-shaped connection terminals arranged in a step form or a grid form and an insulating film provided to a wiring connected with the respective land-shaped connection terminals; and
a semiconductor chip mounted on the flexible printed circuit.

2. A semiconductor device according to claim 2, wherein the land-shaped connection terminals are commonly used as terminals for electrical test.

3. A method of manufacturing a semiconductor device, comprising the steps of:
forming a flexible printed circuit including a connection terminal portion in which a plurality of land-shaped connection terminals are arranged in a step form or a grid form and an insulating film is provided to a conductor connected with the respective land-shaped connection terminals;
mounting a semiconductor chip on the flexible printed circuit; and
separating a semiconductor device from the flexible printed circuit by cutting a portion of each of outermost land-shaped connection terminals of the land-shaped connection terminals arranged in the step form or the grid form in the flexible printed circuit.

4. A method of manufacturing a semiconductor device according to claim 3, further comprising a test step of performing an electrical test using the land-shaped connection terminals.

5. A method of manufacturing a semiconductor device according to claim 4, wherein the semiconductor chip is tested in the test step.

6. A method of manufacturing a semiconductor device according to claim 4, wherein a pattern test of the flexible printed circuit is performed in the test step.

7. An electronic device comprising:
a flexible printed circuit having a connection terminal portion that includes a plurality of connection terminal lands arranged in a step form or a grid form and an insulating film provided to a wiring connected with the respective connection terminal lands;
a semiconductor chip mounted on the flexible printed circuit; and
an electronic part operated at a time when an output signal from the semiconductor chip is inputted through the plurality of connection terminal lands.

8. An electronic device according to claim 7, wherein the electronic part comprises a terminal portion provided in a region connected with the flexible printed circuit, and the terminal portion comprises a plurality of terminals provided at positions opposed to the connection terminal lands of the flexible printed circuit and a plurality of wirings which are connected with the terminals and covered with an insulating film.

9. An electronic device according to claim 7, wherein the electronic part is a display panel having a display screen.
